(19) United States
(12) Patent Application Publication
(10) Pub. No.: US 2023/0260315 A1
(43) Pub. Date: Aug. 17, 2023

(54) FINGERPRINT SENSING SYSTEM

(71) Applicant: Egis Technology Inc., Hsinchu City (TW)

(72) Inventors: Tong-Long Fu, Hsinchu City (TW); Wei Jung Wang, Hsinchu City (TW)

(73) Assignee: Egis Technology Inc., Hsinchu City (TW)

(21) Appl. No.: 17/768,856

(22) PCT Filed: Oct. 19, 2020
(86) PCT No.: PCT/CN2020/121897

§ 371 Date: Apr. 14, 2022

Related U.S. Application Data
(60) Provisional application No. 62/984,272, filed on Mar. 2, 2020.
(60) Provisional application No. 62/986,796, filed on Mar. 9, 2020.

(51) Int. Cl. G06V 40/13

(52) U.S. Cl. CPC G06V 40/1318; G02B 5/201

(57) ABSTRACT

Provided is a fingerprint sensing system disposed under a display. The fingerprint sensing system includes a sensor and a controller. The sensor has a plurality of sensing pixels arranged into an array, and the sensing pixels includes at least one functional sensing pixel. The controller is electrically connected to the sensor. The controller calculates an environmental parameter according to a signal obtained by the at least one functional sensing pixel.

### BACKGROUND

### Technical Field

The invention relates to a sensing system, and in particular to a fingerprint sensing system.

### Description of Related Art

An electronic product such as a smart phone and a mobile device is one of necessary tools in people's lives. Generally speaking, such an electronic product is equipped with a sensing device for the external environment, for example, for sensing a luminous intensity of environmental light or sensing a distance between an external object and a display of the electronic product. Sensing the luminous intensity of the environmental light helps the electronic product to adjust display brightness of the display, improving the user experience. In addition, sensing the distance between an external object and the display of the electronic product also helps the electronic product to determine whether it is required to turn off a display screen of the display, for example, during conversation of the user or in the case where the electronic product is placed in a bag or a pocket.

However, the above-mentioned sensing for the external environment requires a corresponding sensing device additionally mounted in the electronic product, which not only increases production costs, but also occupies the front position of the electronic product, therefore affecting the size of the display screen.

### SUMMARY

The invention is directed to a fingerprint sensing system, which may be used to sense changes in an external environmental light field. The changes in the light field include properties such as a luminous intensity, a color, and a frequency of change in the luminous intensity.

A fingerprint sensing system of an embodiment of the invention is disposed under a display. The fingerprint sensing system includes a sensor and a controller. The sensor has a plurality of sensing pixels arranged into an array. The sensing pixels include at least one functional sensing pixel. The controller is electrically connected to the sensor. The controller calculates an environmental light field parameters according to a signal obtained by the at least one functional sensing pixel.

Based on the foregoing, in the fingerprint sensing system of an embodiment of the invention, since the controller calculates the environmental parameter according to the signal of the environmental light obtained by the functional sensing pixel, the fingerprint sensing system may be used to sense the external environment, so that an electronic product using the embodiments of the invention has a relatively low cost.

### BRIEF DESCRIPTION OF THE DRAWINGS

FIG. 1 is a schematic diagram of a fingerprint sensing system adapted for sensing a luminous intensity of environmental light according to an embodiment of the invention.

FIG. 2 is a schematic diagram of a fingerprint sensing system according to an embodiment of the invention.

FIG. 3 is a schematic diagram of a fingerprint sensing system according to an embodiment of the invention.

FIG. 4 is a schematic diagram of a fingerprint sensing system according to an embodiment of the invention.

FIG. 5 is a schematic diagram of a fingerprint sensing system according to an embodiment of the invention.

FIG. 6 is a schematic diagram of a plurality of sensing pixels forming one environmental light sensing pixel in a fingerprint sensing system according to an embodiment of the invention.

FIG. 7 schematically shows a distribution diagram of environmental light sensing pixels in a fingerprint sensing system according to an embodiment of the invention.

FIG. 8A to FIG. 8D each show a schematic distribution diagram of environmental light sensing pixels in a fingerprint sensing system according to an embodiment of the invention.

FIG. 9 is a schematic diagram of a fingerprint sensing system adapted for sensing a distance between an object and a display according to another embodiment of the invention.

FIG. 10 is a schematic diagram of a fingerprint sensing system according to another embodiment of the invention.

FIG. 11 is a schematic diagram of a fingerprint sensing system according to another embodiment of the invention.

FIG. 12 is a schematic diagram of a fingerprint sensing system according to another embodiment of the invention.

FIG. 13 is a schematic diagram of a fingerprint sensing system according to another embodiment of the invention.

FIG. 14 schematically shows a distribution diagram of environmental light sensing pixels and a distance sensing pixel in a fingerprint sensing system adapted for sensing both a luminous intensity of environmental light and a distance between an object and a display according to another embodiment of the invention.

### DESCRIPTION OF REFERENCE SIGNS

100, 100A, 100B, 100C, 100D, 100′, 100A′, 100B′, 100C′, 100D′: fingerprint sensing system
110: sensor
112: sensing pixel
112-1, 112-1A, 112-2, 112-3, 112-4, 112-5: environmental light sensing pixel
112-1′: first distance sensing pixel
112-2′: second distance sensing pixel
120, 120B, 120′: light-filtering pixel pattern layer
122-1, 122-1B, 122-2, 122-2R, 122-3G, 122-4R, 122-5B: light-filtering pixel
130, 130A: optical layer
140: substrate
150: controller
160: light-transmitting layer
170-1: first light source
170-2: second light source
180: light-filtering layer
200: display
300: environmental light
B1: first light beam
B2: second light beam
C1, C2: curve
O: object
P: central position
RB1: first reflection light beam
RB2: second reflection light beam
θ: field angle

### DESCRIPTION OF THE EMBODIMENTS

Reference will now be made in detail to exemplary embodiments of the invention, examples of which are illustrated in the accompanying drawings. Wherever possible, the same reference numerals are used in the drawings and description to refer to the same or like parts.

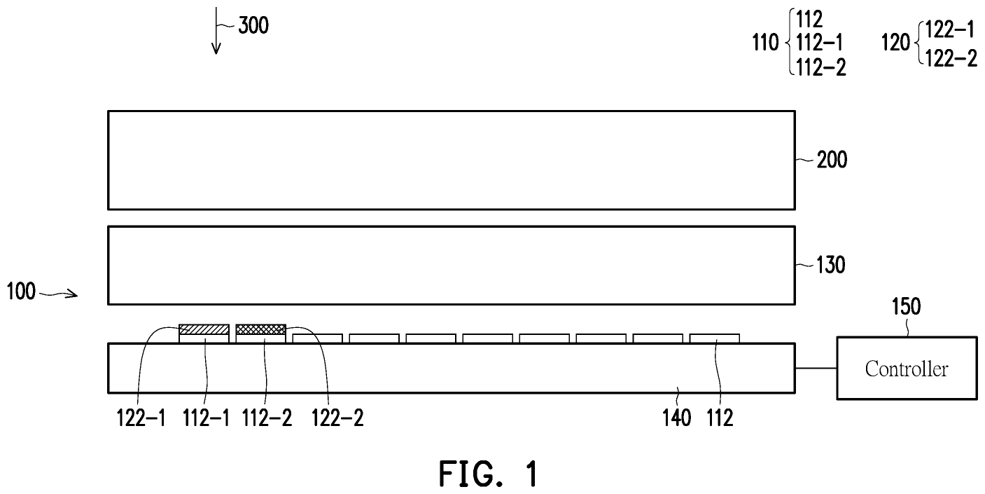

FIG. 1 is a schematic diagram of a fingerprint sensing system adapted for sensing a luminous intensity of environmental light according to an embodiment of the invention. With reference to FIG. 1, a fingerprint sensing system 100 is disposed under a display 200. The fingerprint sensing system 100 includes a sensor 110 and a controller 150.

In this embodiment, the display 200 is, for example, a display panel (e.g., a transparent display panel), a touch display panel (e.g., a transparent touch display panel), or a combination of the above with a finger pressure plate. For example, the display 200 is an organic light-emitting diode display panel (OLED display panel), but the invention is not limited thereto. Alternatively, the display 200 may be a touch display panel, such as an organic light-emitting diode display panel having a plurality of touch electrodes. The touch electrodes may be formed on the outer surface of the organic light-emitting diode display panel or embedded in the organic light-emitting diode display panel, and the touch electrodes may perform touch detection in a self-capacitance mode or mutual-capacitance mode. Alternatively, the display 200 may be a combination of a finger pressure plate with a display panel or a combination of a finger pressure plate with a touch display panel.

In this embodiment, the sensor 110 may be disposed on a substrate 140. The substrate 140 may be a printed circuit board (PCB) or a flexible printed circuit (FPC). The sensor 110 may be a light sensor of a thin film transistor (TFT), complementary metal oxide semiconductor (CMOS), or charge coupled device (CCD). Besides, the sensor 110 has a plurality of sensing pixels 112 arranged into an array, and each sensing pixel 112 may include at least one photodiode, but the invention is not limited thereto. During fingerprint sensing, a user moves a finger close to or places a finger on the display 200, the display 200 emits an irradiating light beam to irradiate the finger, and a reflection light beam is generated after reflected by the finger. The reflection light beam is sequentially transmitted through the display 200 and an optical layer 130, and then transmitted to the sensor 110 for fingerprint sensing. In addition, the sensing pixels 112 include at least one functional sensing pixel. In FIG. 1, the functional sensing pixel in the sensing pixel 112 includes environmental light sensing pixels 112-1 and 112-2.

In this embodiment, the fingerprint sensing system 100 is placed under environmental light 300. The source or form of the environmental light 300 is not limited by the invention. After passing through the display 200 and the optical layer 130, the environmental light 300 is received by the environmental light sensing pixels 112-1 and 112-2. The controller 150 is electrically connected to the sensor 110. The controller 150 calculates an environmental parameter according to a signal obtained by the sensing pixels. In FIG. 1, the environmental parameter is a luminous intensity of the environmental light 300.

In this embodiment, the fingerprint sensing system 100 further includes the optical layer 130. The optical layer 130 is disposed between the display 200 and the sensor 110. The optical layer 130 may be a lens layer, such as a lens group layer or a micro-lens layer, but the invention is not limited thereto. In the fingerprint sensing system 100 of an embodiment of the invention, since the optical layer 130 may be a lens layer and the optical layer 130 helps light convergence, the signal-to-noise ratio of the luminous intensity of the environmental light 300 sensed and the signal-to-noise ratio of an fingerprint image obtained by the fingerprint sensing system 100 are relatively high.

In this embodiment, the fingerprint sensing system 100 further includes a light-filtering pixel pattern layer 120. The light-filtering pixel pattern layer 120 is disposed on part of the environmental light sensing pixels 112-1 and 112-2, and is disposed between the optical layer 130 and the sensor 110. Specifically, the light-filtering pixel pattern layer 120 includes at least one light-filtering pixel 122-1 and 122-2. Each of the light-filtering pixels 122-1 and 122-2 is, for example, a multilayer interference film, a thin film using the principle of surface plasmon resonance, or a diffraction grating film, but the invention is not limited thereto. In this embodiment, transmittance spectrums of the light-filtering pixels 122-1 and 122-2 may be the same as or different from each other.

Taking FIG. 1 as an example, the light-filtering pixel pattern layer 120 is directly disposed on the environmental light sensing pixels 112-1 and 112-2, and is disposed on all of the environmental light sensing pixels 112-1 and 112-2. The transmittance spectrums of the light-filtering pixels 122-1 and 122-2 of the light-filtering pixel pattern layer 120 are different from each other, for example, a transmittance spectrum within the visible light wavelength band from 400 nanometers (nm) to 700 nm or a transmittance spectrum within the near-infrared wavelength band of 700 nm to 1000 nm. In FIG. 1, the environmental light 300 transmitted through the light-filtering pixels 122-1 and 122-2 is then respectively received by the environmental light sensing pixels 112-1 and 112-2, so that the environmental light sensing pixels 112-1 and 112-2 respectively obtain signals E1 and E2. The controller 150 calculates the luminous intensity of the environmental light 300 according to a ratio E1/E2 between the signals E1 and E2, and may also obtain the intensity of the environmental light 300 with reference to an intensity without the light-filtering pixel layer and a proportional relationship between E1 and E2. In the fingerprint sensing system 100 of an embodiment of the invention, since the light-filtering pixel pattern layer 120 is directly disposed on the environmental light sensing pixels 112-1 and 112-2, the fingerprint sensing system 100 has a relatively low cost and a relatively small overall thickness. Furthermore, since the controller 150 of the fingerprint sensing system 100 calculates the luminous intensity of the environmental light 300 according to the ratio E1/E2 between the signals obtained by the environmental light sensing pixels 112-1 and 112-2, the calculated luminous intensity of the environmental light 300 has a relatively high reliability. Besides, the property of frequency of change in the luminous intensity of environmental light may be obtained from a change in the intensity of E1 or E2 with time.

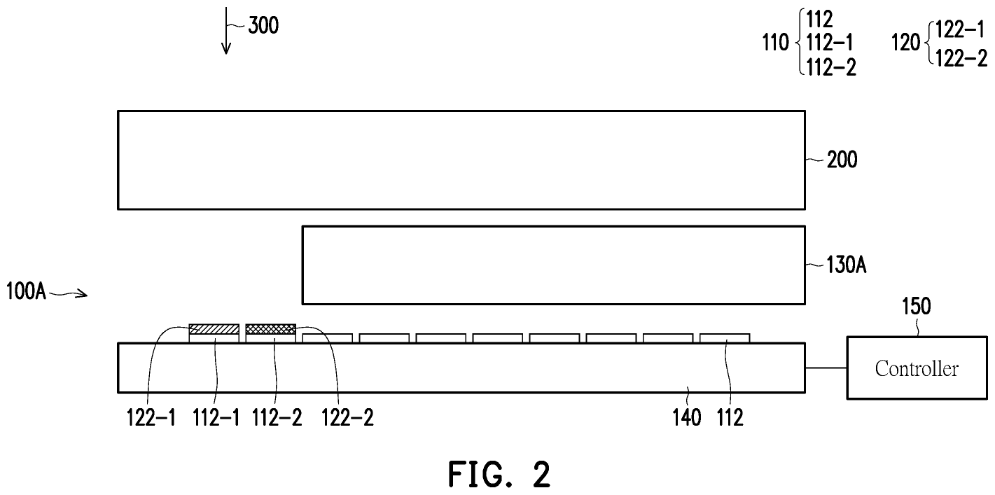

FIG. 2 is a schematic diagram of a fingerprint sensing system according to an embodiment of the invention. With reference to FIG. 2, a fingerprint sensing system 100A of FIG. 2 is similar to the fingerprint sensing system 100 of FIG. 1, and is mainly different in that an optical layer 130A is not disposed between the environmental light sensing pixels 112-1, 112-2 and the display 200, and the optical layer 130A is not disposed between the light-filtering pixel pattern layer 120 and the display 200. In this embodiment, the optical layer 130A may be a structural layer limiting a light receiving angle with a collimator effect, such as a light guide plate with optical fiber elements, or a collimating element with alternately arranged light-transmitting regions and light-shielding regions. In the fingerprint sensing system 100A of an embodiment of the invention, the optical layer 130A of the fingerprint sensing system 100A is not disposed between the environmental light sensing pixels 112-1, 112-2 and the display 200, and the optical layer 130A may be a structural layer limiting a light receiving angle. Therefore, the optical layer 130A shielding large-angle stray light increases the signal-to-noise ratio of fingerprint sensing. In addition, the environmental light sensing pixels 112-1 and 112-2 can still receive the environmental light 300 incident at a large angle, so that the fingerprint sensing system 100A can still have a good sensing effect for the luminous intensity of the environmental light 300.

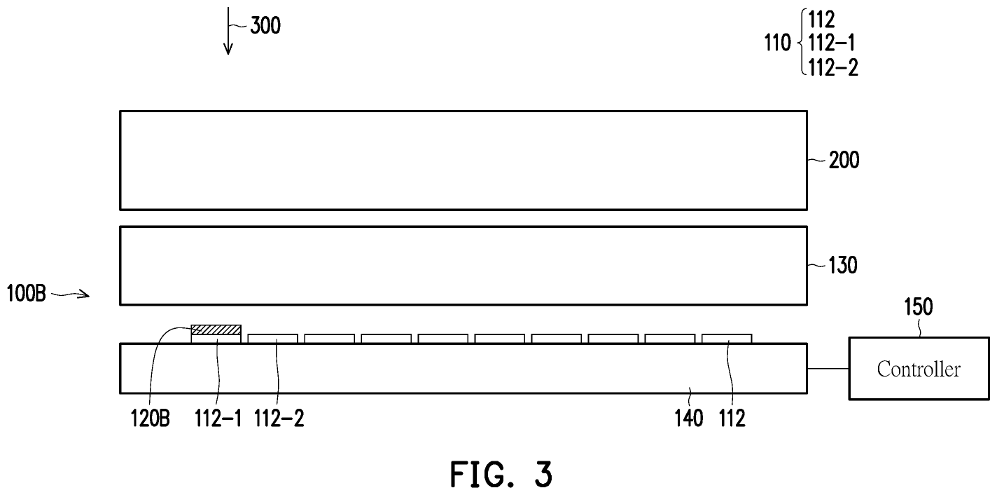

FIG. 3 is a schematic diagram of a fingerprint sensing system according to an embodiment of the invention. With reference to FIG. 3, a fingerprint sensing system 100B of FIG. 3 is similar to the fingerprint sensing system 100 of FIG. 1, and is mainly different in that a light-filtering pixel pattern layer 120B is not disposed on at least one of the environmental light sensing pixels 112-1 and 112-2. FIG. 3 shows that the light-filtering pixel pattern layer 120B is not disposed at a position corresponding to the environmental light sensing pixel 112-2. In the fingerprint sensing system 100B of an embodiment of the invention, since it is not necessary to dispose the light-filtering pixel pattern layer 120B at a position corresponding to each of the environmental light sensing pixels 112-1 and 112-2, the fingerprint sensing system 100B has a relatively low manufacturing cost.

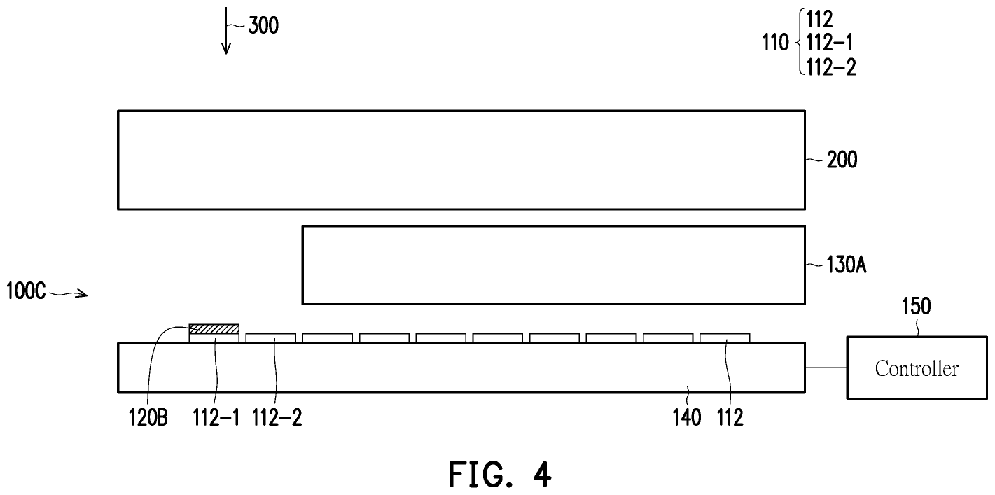

FIG. 4 is a schematic diagram of a fingerprint sensing system according to an embodiment of the invention. With reference to FIG. 4, a fingerprint sensing system 100C of FIG. 4 is similar to the fingerprint sensing system 100A of FIG. 2, and is mainly different in that the light-filtering pixel pattern layer 120B is not disposed on at least one of the environmental light sensing pixels 112-1 and 112-2. In the fingerprint sensing system 100C of an embodiment of the invention, since it is not necessary to dispose the light-filtering pixel pattern layer 120B at a position corresponding to each of the environmental light sensing pixels 112-1 and 112-2, the fingerprint sensing system 100C has a relatively low manufacturing cost.

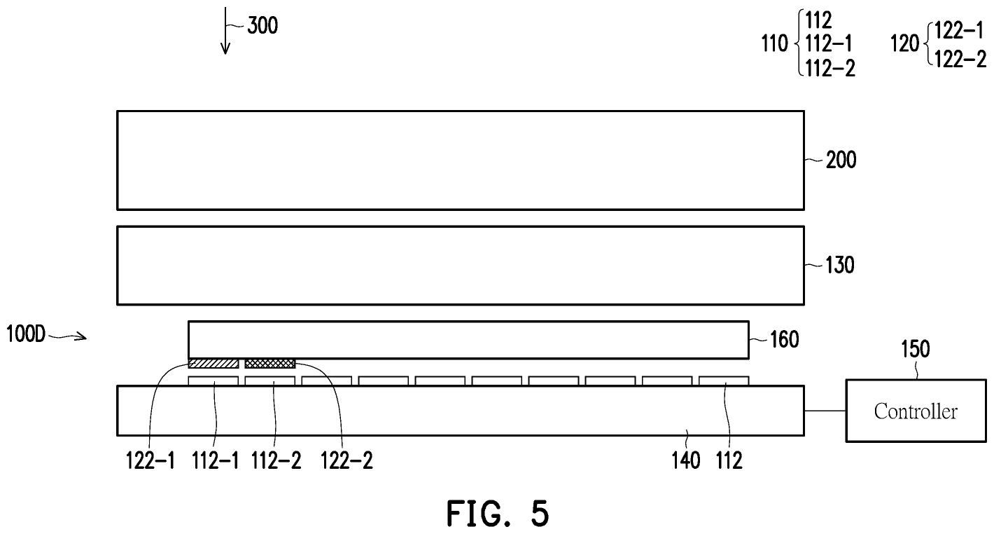

FIG. 5 is a schematic diagram of a fingerprint sensing system according to an embodiment of the invention. With reference to FIG. 5, a fingerprint sensing system 100D of FIG. 5 is similar to the fingerprint sensing system 100 of FIG. 1, and is mainly different in that the fingerprint sensing system 100D of FIG. 5 further includes a light-transmitting layer 160. In this embodiment, the material of the light-transmitting layer 160 is, for example, a transparent material such as glass. The light-filtering pixel pattern layer 120 is directly disposed at a position on the light-transmitting layer 160 corresponding to the environmental light sensing pixels 112-1 and 112-2. Furthermore, FIG. 5 shows that the light-filtering pixel pattern layer 120 is preferably disposed on a surface of the light-transmitting layer 160 facing the sensor 110, but the invention is not limited thereto. In an embodiment, the light-filtering pixel pattern layer 120 may also be disposed on a surface of the light-transmitting layer 160 away from the sensor 110. When the light-filtering pixel pattern layer 120 is not suitable for being directly disposed on the sensing pixels 112 in the process, since the light-filtering pixel pattern layer 120 may be directly disposed on the light-transmitting layer 160, in the fingerprint sensing system 100D of an embodiment of the invention, a relatively great number of forms or types of materials may be adopted for the light-filtering pixel pattern layer 120, improving flexibility during the manufacturing process of the fingerprint sensing system 100D.

In another embodiment, the light-transmitting layer 160 may also be replaced with an IR cut-off filter. That is to say, the light-filtering pixel pattern layer 120 may be directly disposed on the IR cut filter. At this time, a reflection light beam received by the fingerprint sensing device 100D may be visible light, and it is also only necessary to design the transmittance spectrum of the light-filtering pixel pattern layer 120 for the visible light wavelength band.

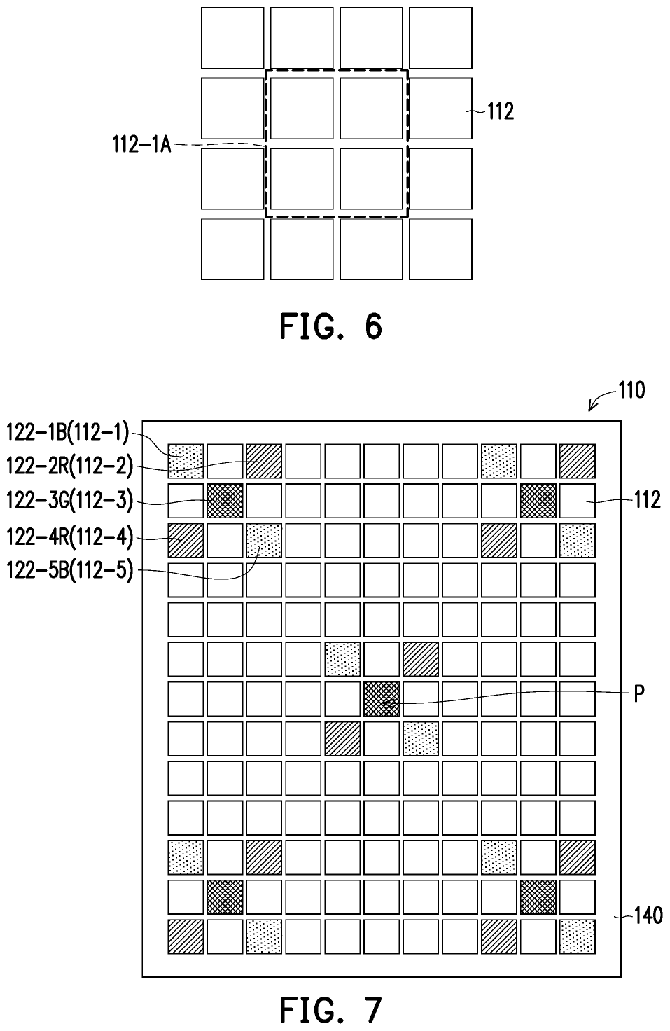

FIG. 6 is a schematic diagram of a plurality of sensing pixels forming one environmental light sensing pixel in a fingerprint sensing system according to an embodiment of the invention. In the fingerprint sensing system shown in FIG. 1 to FIG. 5, each of the environmental light sensing pixels 112-1 and 112-2 is one of the sensing pixels 112 of the sensor 110. In another embodiment, each one environmental light sensing pixel 112-1A may be formed by multiple sensing pixels 112. With reference to FIG. 6, FIG. 6 illustrates an environmental light sensing pixel 112-1A formed by four sensing pixels 112. In the fingerprint sensing system of an embodiment of the invention, since the environmental light sensing pixel 112-1A is formed by multiple sensing pixels 112, the controller 150 may increase the signal-to-noise ratio of the obtained signal of the environmental light 300 by, for example, pixel binning to also increase the signal-to-noise ratio of the calculated luminous intensity of the environmental light 300.

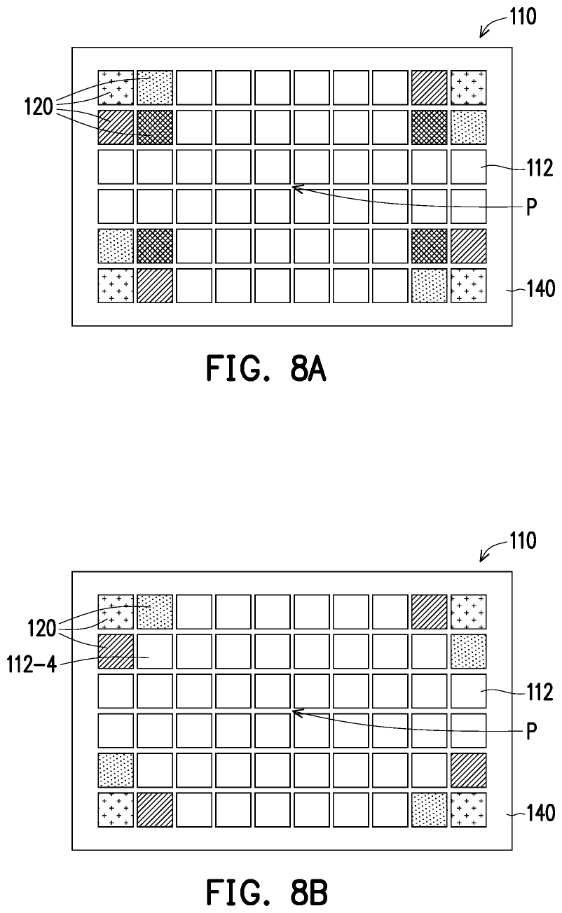

FIG. 7 schematically shows a distribution diagram of environmental light sensing pixels in a fingerprint sensing system according to an embodiment of the invention. FIG. 7 illustrates a preferred arrangement of environmental light sensing pixels 112-1, 112-2, 112-3, 112-4, 112-5 and the light-filtering pixel pattern layer 120. In FIG. 7, the environmental light sensing pixels 112-1, 112-2, 112-3, 112-4, and 112-5 are symmetrically distributed around a central position P of the sensor 110. In an embodiment, the light-filtering pixel pattern layer 120 includes three different transmittance spectrums. Light-filtering pixels 122-2R and 122-4R have the same transmittance spectrum (e.g., red pixels), a light-filtering pixel 122-2G has another transmittance spectrum (e.g., green pixel), and light-filtering pixels 122-1B and 122-5B have still another transmittance spectrum (e.g., blue pixels). In this embodiment, light-filtering pixels having the same transmittance spectrum are symmetrically distributed around a central position P of the array formed by arranging the sensing pixels 112. In an embodiment, since the environmental light sensing pixels 112-1, 112-2, 112-3, 112-4, 112-5 and the light-filtering pixels having the same transmittance spectrum in the light-filtering pixel pattern layer 120 are symmetrically distributed around the central position P of the sensor 110, the fingerprint sensing system has approximately the same sensing capability at different angles, increasing the reliability of the obtained luminous intensity of the environmental light 300.

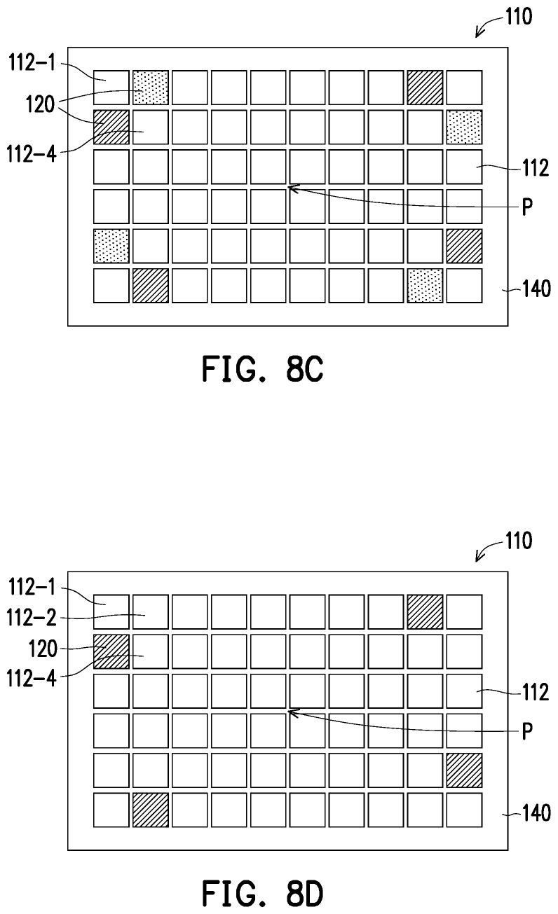

FIG. 8A to FIG. 8D each show a schematic distribution diagram of environmental light sensing pixels in a fingerprint sensing system according to an embodiment of the invention. With reference to FIG. 8A to FIG. 8D, FIG. 8A to FIG. 8D illustrate multiple possible options for configuration of the light-filtering pixel pattern layer 120. Similar to FIG. 7, environmental light sensing pixels and light-filtering pixels having the same transmittance spectrum in the light-filtering pixel pattern layer 120 in FIG. 8A to FIG. 8D are symmetrically or evenly distributed around the central position P of the sensor 110, and the light-filtering pixel pattern layer 120 includes at least two light-filtering pixels.

In another embodiment, the light-filtering pixel pattern layer 120 includes at least three different transmittance spectrums, as shown in FIG. 8A and FIG. 8B. The controller 150 calculates a color temperature of the environmental light 300 according to a ratio between the signals obtained by the environmental light sensing pixels 112-1, 112-2, 112-3, and 112-4.

Besides, in an embodiment, the environmental light sensing pixel of the fingerprint sensing system may be configured as only one of the sensing pixels 112. At this time, the transmittance spectrum of the light-filtering pixel corresponding to the environmental light sensing pixel is preferably similar to the curve of the visual spectrum of the human eye. That is to say, the light-filtering pixel pattern layer 120 includes only one transmittance spectrum.

Based on the above, in the fingerprint sensing system of an embodiment of the invention, the functional sensing pixel includes the environmental light sensing pixel, and the controller calculates the luminous intensity of the environmental light according to the signal obtained by the environmental light sensing pixel. Therefore, the fingerprint sensing system may sense the fingerprint and the luminous intensity of environmental light at the same time, so that an electronic product using the embodiments of the invention has a relatively low cost.

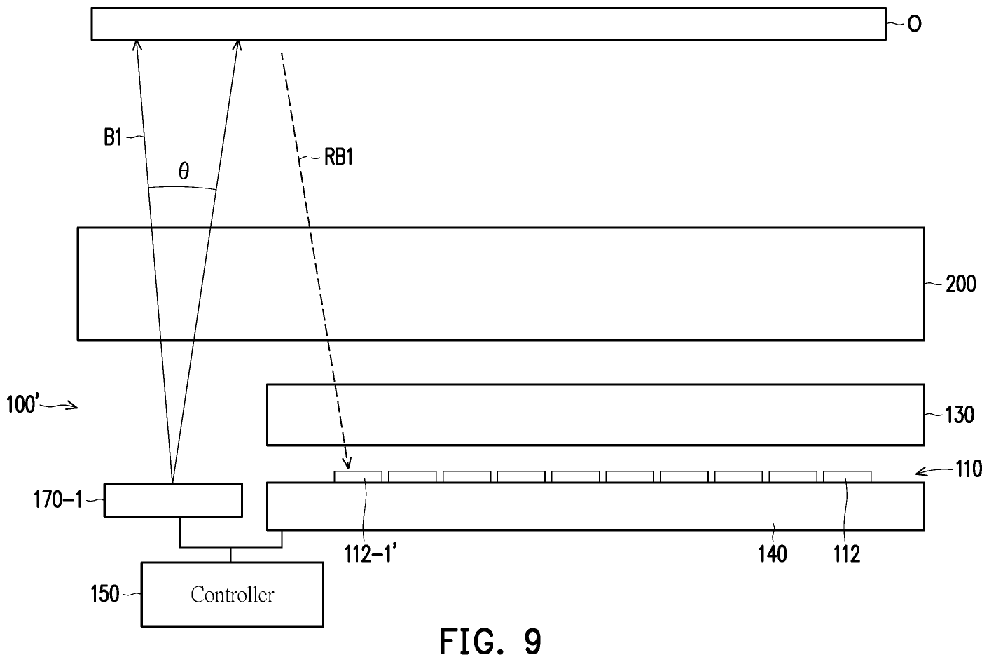

FIG. 9 is a schematic diagram of a fingerprint sensing system adapted for sensing a distance between an object and a display according to another embodiment of the invention. With reference to FIG. 9, a fingerprint sensing system 100′ of FIG. 9 is similar to the fingerprint sensing system 100 of FIG. 1, and is mainly different in that a functional sensing pixel of the fingerprint sensing system 100′ includes at least one first distance sensing pixel 112-1′, and the environmental parameter is a distance between an object O and the display 200.

In this embodiment, the fingerprint sensing system 100′ further includes a first light source 170-1. The first light source 170-1 may be a light-emitting diode or a laser diode, and emits a first light beam B1. The wavelength of the first light beam B1 preferably falls within the range of infrared frequency spectrum, such as 850 nm, 940 nm, or 1350 nm. When the wavelength of the first light beam B1 is selected to be 940 nm or 1350 nm, the first distance sensing pixel 112-1′ is subject to a relatively little influence by sunlight. When the wavelength of the first light beam B1 is selected to be 850 nm, the manufacturing process of the first distance sensing pixel 112-1′ is relatively simple. In an embodiment, a field angle θ of the first light beam B1 falls within a range of ±30 degrees. In a preferred embodiment, the field angle θ of the first light beam B1 falls within a range of ±10 degrees.

In this embodiment, the first light source 170-1 is disposed on a side of the sensor 110 adjacent to the first distance sensing pixel 112-1′. The first distance sensing pixel 112-1′ is located in a periphery region of the sensor 110.

In this embodiment, the controller 150 is electrically connected to the sensor 110 and the first light source 170-1. The controller 150 controls the first light source 170-1 to emit the first light beam B1, so that the object O is irradiated by the first light beam B1 to generate a first reflection light beam RB1. The object O is, for example, a face of the user, a bag of the user, or a pocket. Furthermore, the controller 150 calculates the distance between the object O and the display 200 according to a luminous intensity of the first reflection light beam RB1, a time of flight, or a phase difference between light source modulation signals obtained by the first distance sensing pixel 112-1′. For example, an increasing luminous intensity of the first reflection light beam RB1 indicates a gradually approaching object O, or a decreasing luminous intensity of the first reflection light beam RB1 indicates a gradually departing object O. If the parameter of time of flight is sensed, it is required that the sensing element detects the time when light is reflected from the object O, and then the distance between the object O and the display 200 can be calculated. If the phase difference between light source modulation signals is sensed, it is required that the light source modulates its intensity with time, and the sensing element detects the phase difference of reflection by the object O relative to the light source modulation to obtain the distance between the object O and the display 200.

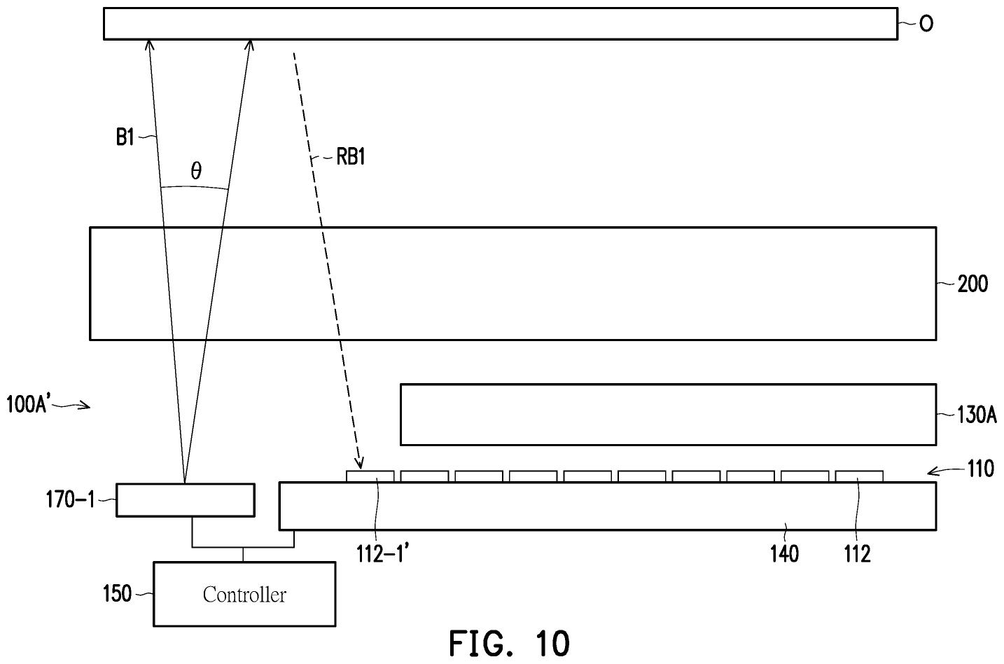

FIG. 10 is a schematic diagram of a fingerprint sensing system according to another embodiment of the invention. With reference to FIG. 10, a fingerprint sensing system 100A′ of FIG. 10 is similar to the fingerprint sensing system 100′ of FIG. 9, and is mainly different in that the optical layer 130A is not disposed between the first distance sensing pixel 112-1′ and the display 200. In this embodiment, the advantages of not disposing the optical layer 130A of the fingerprint sensing system 100A′ between the first distance sensing pixel 112-1′ and the display 200 and configuring the optical layer 130A as a light-limiting structural layer are similar to those of the optical layer 130A of the fingerprint sensing system 100A in FIG. 2, and will not be repeatedly described here.

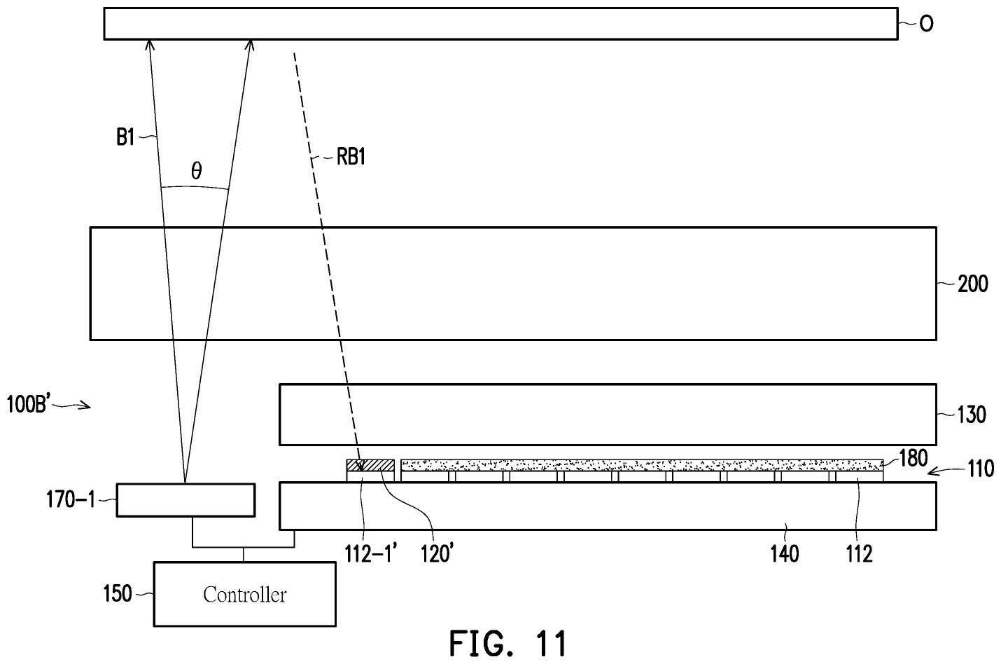

FIG. 11 is a schematic diagram of a fingerprint sensing system according to another embodiment of the invention. With reference to FIG. 11, in this embodiment, a fingerprint sensing system 100B′ further includes a light-filtering pixel pattern layer 120′. The light-filtering pixel pattern layer 120′ includes at least one light-filtering pixel and includes at least one transmittance spectrum. The transmittance spectrum of the light-filtering pixel preferably falls within a range allowing the first reflection light beam RB1 to pass. The light-filtering pixel pattern layer 120′ is, for example, an IR bandpass filter. In this embodiment, the light-filtering pixel pattern layer 120′ is disposed on the first distance sensing pixel 112-1′, and is disposed between the optical layer 130 and the sensor 110. In FIG. 11, the light-filtering pixel pattern layer 120′ is directly disposed on the first distance sensing pixel 112-1′.

In an embodiment, the fingerprint sensing system 100B′ further includes a light-filtering layer 180, disposed between the optical layer 130 and the sensor 110. The spectral form of the light-filtering layer 180 should conform to the wavelength band of an irradiating light beam for fingerprint sensing. For example, the light-filtering layer 180 may be an IR cut-off filtering layer.

In this embodiment, the light-filtering layer 180 is disposed on the sensing pixels except the first distance sensing pixel 112-1′. In an embodiment, the light-filtering layer 180 may be directly disposed on the sensing pixels 112. The advantages of directly disposing the light-filtering pixel pattern layer 120′ on the first distance sensing pixel 112-1′ or directly disposing the light-filtering layer 180 on the sensing pixels 112 are similar to those of the fingerprint sensing system 100 in FIG. 1 and will not be repeatedly described here.

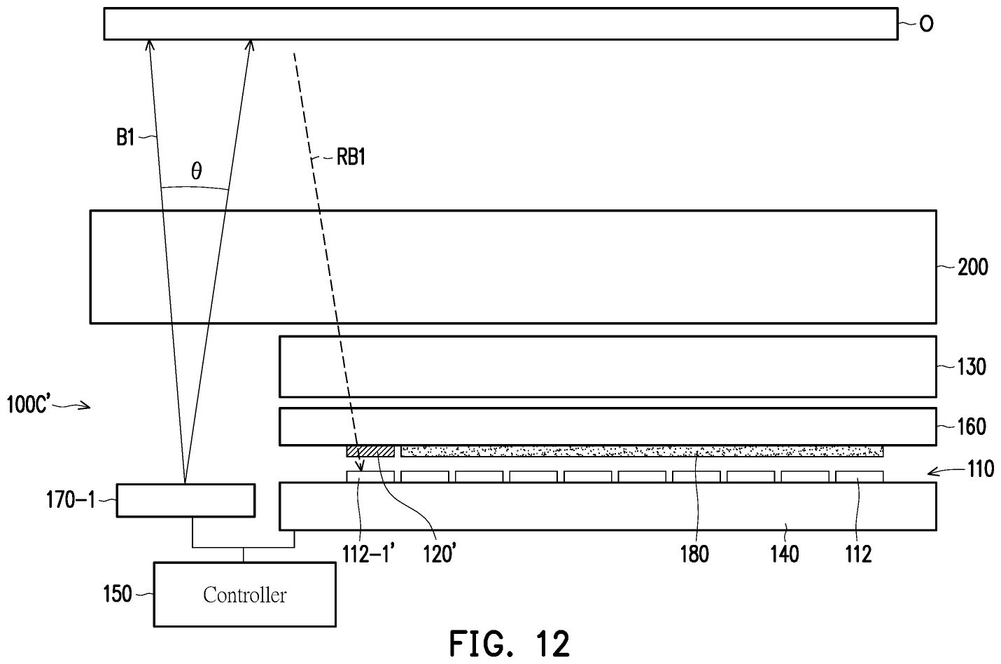

FIG. 12 is a schematic diagram of a fingerprint sensing system according to another embodiment of the invention. A fingerprint sensing system 100C′ of FIG. 12 is similar to the fingerprint sensing system 100B′ of FIG. 12, and is mainly different in that the fingerprint sensing system 100C′ further includes the light-transmitting layer 160. The light-transmitting layer 160 is disposed between the optical layer 130 and the sensor 110. The light-filtering pixel pattern layer 120′ is directly disposed at a position on the light-transmitting layer 160 corresponding to the first distance sensing pixel 112-1′, and the light-filtering layer 180 is directly disposed in a region of the light-transmitting layer 160 corresponding to the sensing pixels 112 except the first distance sensing pixel 112-1′. The advantages of directly disposing the light-filtering pixel pattern layer 120′ and the light-filtering layer 180 on the light-transmitting layer 160 are similar to those of FIG. 5, and will not be repeatedly described here.

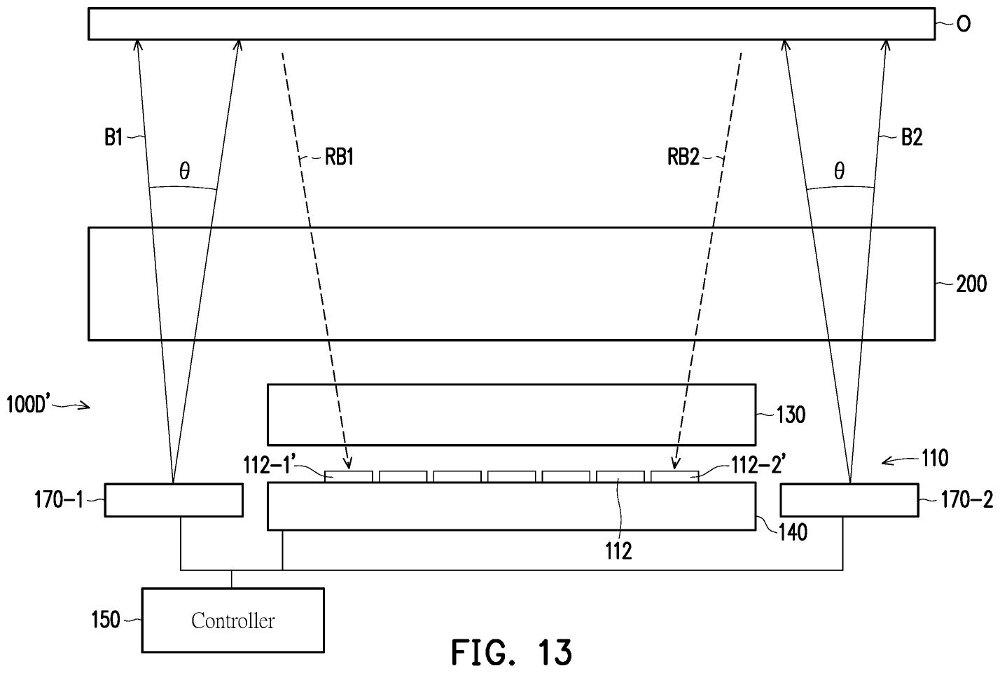

FIG. 13 is a schematic diagram of a fingerprint sensing system according to another embodiment of the invention. A fingerprint sensing system 100D′ of FIG. 13 is similar to the fingerprint sensing system 100′ of FIG. 9, and is mainly different in that the fingerprint sensing system 100D′ further includes a second light source 170-2. In this embodiment, the second light source 170-2 may be a light-emitting diode or a laser diode, and is used to emit a second light beam B2. The wavelength of the second light beam B2 preferably falls within the range of infrared frequency spectrum, such as 850 nm, 940 nm, or 1350 nm. The second light source 170-2 is electrically connected to the controller 150. Furthermore, the functional sensing pixel includes a plurality of functional sensing pixels, and the functional sensing pixel includes the first distance sensing pixel 112-1′ and at least one second distance sensing pixel 112-2′.

In this embodiment, the first distance sensing pixel 112-1′ and the second distance sensing pixel 112-2′ are located in a periphery region of the array formed by arranging the sensing pixels 112. The second light source 170-2 is disposed on a side of the array formed by arranging the sensing pixels 112 adjacent to the second distance sensing pixels 112-2′. Moreover, the first light source 170-1 and the second light source 170-2 are respectively disposed on two different sides of the array formed by arranging the sensing pixels 112.

In this embodiment, the controller 150 controls the second light source 170-2 to emit the second light beam B2, so that the object O is irradiated by the second light beam B2 to generate a second reflection light beam RB2. The controller 150 calculates the distance between the object O and the display 200 according to a luminous intensity of the second reflection light beam RB2 obtained by the second distance sensing pixel 112-2′. In an embodiment, the first distance sensing pixel 112-1′ and the second distance sensing pixel 112-2′ may be respectively configured to sense different distance ranges. For example, the first distance sensing pixel 112-1′ is configured to sense a relatively far distance range, and the second distance sensing pixel 112-2′ is configured to sense a relatively close distance range. At this time, a luminous intensity of the first light beam B1 is greater than a luminous intensity of the second light beam B2. In another embodiment, the controller 150 controls the first light source 170-1 and the second light source 170-2 to respectively emit the first light beam B1 and the second light beam B2 at different timings, so that the first distance sensing pixel 112-1′ is subject to a relatively little influence by the first reflection light beam RB1 and the second distance sensing pixel 112-2′ is subject to a relatively little influence by the second reflection light beam RB2.

In an embodiment, the controller 150 may calculate a relative angle between the object O and the display 200 according to the luminous intensity of the first reflection light beam RB1 and the luminous intensity of the second reflection light beam RB2. For example, the controller 150 may calculate a first distance between the object O and the display 200 according to the luminous intensity of the first reflection light beam RB1 and calculate a second distance between the object O and the display 200 according to the luminous intensity of the second reflection light beam RB2. As a result, the controller 150 calculates the relative angle between the object O and the display 200 according to the relationship between the first distance and the second distance.

Based on the above, in the fingerprint sensing system of an embodiment of the invention, the functional sensing pixel includes the distance sensing pixel, and the controller may calculate the distance between an object and the display according to the luminous intensity of the reflection light beam, the time of flight, or the phase difference between light source modulation signals obtained by the distance sensing pixel. Therefore, the fingerprint sensing system may sense the fingerprint and the distance at the same time, so that an electronic product using the embodiments of the invention has a relatively low cost.

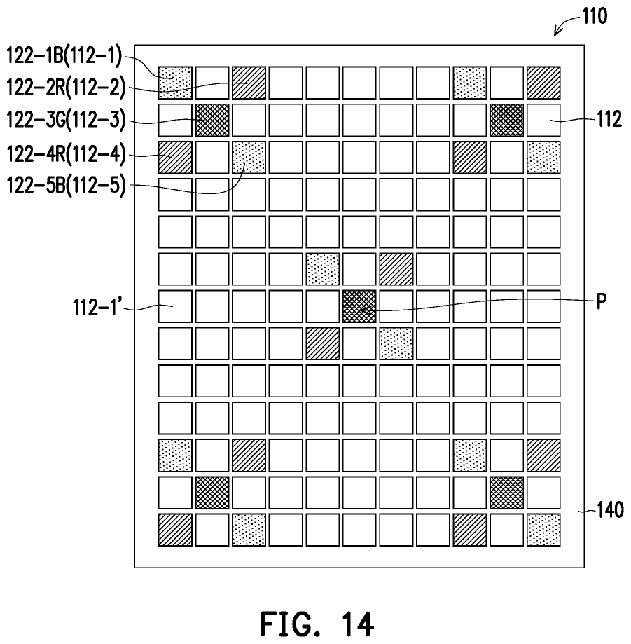

FIG. 14 schematically shows a distribution diagram of environmental light sensing pixels and a distance sensing pixel in a fingerprint sensing system adapted for sensing both a luminous intensity of environmental light and a distance between an object and a display according to another embodiment of the invention. With reference to FIG. 14, in the fingerprint sensing system of an embodiment of the invention, the functional sensing pixel may include a plurality of functional sensing pixels, and the functional sensing pixels include the environmental light sensing pixels 112-1, 112-2, 112-3, 112-4, 112-5 and the first distance sensing pixel 112-1′. That is to say, the fingerprint sensing system may sense the fingerprint, the environmental light, and the distance at the same time. In another embodiment, the functional sensing pixel further includes a second distance sensing pixel, as shown in FIG. 13. The elements in the fingerprint sensing system and the relationship between the elements are similar to those in FIG. 1 to FIG. 13, and will not be repeatedly described here.

In summary of the foregoing, in the fingerprint sensing system of an embodiment of the invention, since the sensing pixels include the functional sensing pixels, and the controller calculates the environmental parameter according to the signals obtained by the functional sensing pixels, the fingerprint sensing system may sense the fingerprint and the environmental parameter at the same time, so that an electronic product using the embodiments of the invention has a relatively low cost.

Lastly, it should be noted that the above embodiments are only used for describing, instead of limiting, the technical solution of the invention. Although the invention has been described in detail with reference to the above embodiments, those of ordinary skill in the art should understand that modification to the technical solutions recited in the above embodiments, or equivalent replacement of some or all of the technical features may still be made. Nonetheless, the nature of the corresponding technical solutions so modified or replaced does not depart from the scope of the technical solutions of the embodiments of the invention.

What is claimed is:

1. A fingerprint sensing system, being disposed under a display, and comprising:
a sensor, having a plurality of sensing pixels arranged into an array, wherein the sensing pixels comprise at least one functional sensing pixel; and
a controller, electrically connected to the sensor,
wherein the controller calculates an environmental parameter according to a signal obtained by the at least one functional sensing pixel.

2. The fingerprint sensing system according to claim 1, further comprising:
an optical layer, disposed between the display and the sensor.

3. The fingerprint sensing system according to claim 2, wherein the optical layer is a lens layer.

4. The fingerprint sensing system according to claim 2, wherein the optical layer is a light-limiting structural layer.

5. The fingerprint sensing system according to claim 4, wherein the optical layer is not disposed between the at least one functional sensing pixel and the display.

6. The fingerprint sensing system according to claim 2, wherein the at least one functional sensing pixel comprises at least one environmental light sensing pixel, and the environmental parameter is a luminous intensity of environmental light.

7. The fingerprint sensing system according to claim 6, further comprising:
a light-filtering pixel pattern layer, disposed on all of the at least one environmental light sensing pixel.

8. The fingerprint sensing system according to claim 6, further comprising:
a light-filtering pixel pattern layer, disposed on part of the at least one environmental light sensing pixel.

9. The fingerprint sensing system according to claim 8, wherein the light-filtering pixel pattern layer is disposed between the optical layer and the sensor.

10. The fingerprint sensing system according to claim 8, wherein the light-filtering pixel pattern layer is directly disposed on the at least one environmental light sensing pixel.

11. The fingerprint sensing system according to claim 8, further comprising:
a light-transmitting layer, disposed between the optical layer and the sensor, wherein the light-filtering pixel pattern layer is directly disposed at a position on the light-transmitting layer corresponding to the at least one environmental light sensing pixel.

12. The fingerprint sensing system according to claim 11, wherein the at least one environmental light sensing pixel comprises a plurality of environmental light sensing pixels, and the environmental light sensing pixels are symmetrically or evenly distributed around a central position of the sensor.

13. The fingerprint sensing system according to claim 12, wherein the light-filtering pixel pattern layer comprises at least two light-filtering pixels, and the at least two light-filtering pixels are symmetrically or evenly distributed around the central position of the sensor.

14. The fingerprint sensing system according to claim 12, wherein the light-filtering pixel pattern layer comprises at least two light-filtering pixels and comprises at least two different transmittance spectrums, and light-filtering pixels having the same transmittance spectrum are symmetrically or evenly distributed around the central position of the sensor.

15. The fingerprint sensing system according to claim 12, wherein the controller calculates the luminous intensity of the environmental light according to a ratio between the signals obtained by the environmental light sensing pixels, or obtains a frequency of change in the luminous intensity of the environmental light from a change of the signals with time.

16. The fingerprint sensing system according to claim 12, wherein the light-filtering pixel pattern layer comprises at least three different transmittance spectrums, and the controller calculates a color temperature of the environmental light according to a ratio between the signals obtained by the environmental light sensing pixels.

17. The fingerprint sensing system according to claim 2, wherein the at least one functional sensing pixel comprises at least one first distance sensing pixel, the environmental parameter is a distance between an object and the display, and the fingerprint sensing system further comprises:
a first light source, used to emit a first light beam,
wherein the controller controls the first light source to emit the first light beam, such that the object is irradiated by the first light beam to generate a first reflection light beam, and the controller calculates the distance between the object and the display according to a luminous intensity of the first reflection light beam, a time of flight, or a phase difference between light source modulation signals obtained by the at least one first distance sensing pixel.

18. The fingerprint sensing system according to claim 17, wherein the first light source is disposed on a side of the sensor adjacent to the at least one first distance sensing pixel.

19. The fingerprint sensing system according to claim 17, wherein the at least one first distance sensing pixel is located in a periphery region of the sensor.

20. The fingerprint sensing system according to claim 17, further comprising:
a light-filtering pixel pattern layer, disposed on the at least one first distance sensing pixel.

21. The fingerprint sensing system according to claim 20, wherein the light-filtering pixel pattern layer is disposed between the optical layer and the sensor.

22. The fingerprint sensing system according to claim 20, wherein the light-filtering pixel pattern layer is directly disposed on the at least one first distance sensing pixel.

23. The fingerprint sensing system according to claim 20, further comprising:
a light-filtering layer, disposed on the sensing pixels except the at least one first distance sensing pixel, and disposed between the optical layer and the sensor.

24. The fingerprint sensing system according to claim 23, further comprising:
a light-transmitting layer, disposed between the optical layer and the sensor, wherein the light-filtering pixel pattern layer is directly disposed at a position on the light-transmitting layer corresponding to the at least one first distance sensing pixel.

25. The fingerprint sensing system according to claim 24, wherein the light-filtering layer is directly disposed in a region of the light-transmitting layer corresponding to the sensing pixels except the at least one first distance sensing pixel.

26. The fingerprint sensing system according to claim 24, further comprising:
a second light source, used to emit a second light beam and electrically connected to the controller,
wherein the at least one functional sensing pixel comprises a plurality of functional sensing pixels, and the functional sensing pixels comprise the at least one first distance sensing pixel and at least one second distance sensing pixel; and
wherein the controller controls the second light source to emit the second light beam, such that the object is irradiated by the second light beam to generate a second reflection light beam, and the controller calculates the distance between the object and the display according to a luminous intensity of the second reflection light beam, a time of flight, or a phase difference between light source modulation signals obtained by the at least one second distance sensing pixel.

27. The fingerprint sensing system according to claim 26, wherein the second light source is disposed on a side of the sensor adjacent to the at least one second distance sensing pixel.

28. The fingerprint sensing system according to claim 26, wherein the first light source and the second light source are respectively disposed on two different sides of the sensor.

29. The fingerprint sensing system according to claim 26, wherein the controller calculates a relative angle between the object and the display according to the luminous intensity of the first reflection light beam and the luminous intensity of the second reflection light beam.

30. The fingerprint sensing system according to claim 2, wherein the at least one functional sensing pixel comprises a plurality of functional sensing pixels, the functional sensing pixels comprise at least one environmental light sensing pixel and at least one first distance sensing pixel, the environmental parameter comprises a luminous intensity of environmental light and a distance between an object and the display, and the fingerprint sensing system further comprises:
a first light source, used to emit a first light beam; wherein
the controller is electrically connected to the sensor and the first light source,
wherein
the controller controls the first light source to emit the first light beam, such that the object is irradiated by the first light beam to generate a first reflection light beam, and the controller calculates the distance between the object and the display according to a luminous intensity of the first reflection light beam, a time of flight, or a phase difference between light source modulation signals obtained by the at least one first distance sensing pixel.

31. The fingerprint sensing system according to claim 30, further comprising:
a light-filtering pixel pattern layer, disposed on all of the at least one environmental light sensing pixel.

32. The fingerprint sensing system according to claim 30, further comprising:
a light-filtering pixel pattern layer, disposed on part of the at least one environmental light sensing pixel.

33. The fingerprint sensing system according to claim 32, wherein the light-filtering pixel pattern layer is disposed between the optical layer and the sensor.

34. The fingerprint sensing system according to claim 32, wherein the light-filtering pixel pattern layer is directly disposed on the at least one environmental light sensing pixel.

35. The fingerprint sensing system according to claim 32, wherein part of the light-filtering pixel pattern layer is disposed on the at least one first distance sensing pixel.

36. The fingerprint sensing system according to claim 35, wherein the light-filtering pixel pattern layer is directly disposed on the at least one first distance sensing pixel.

37. The fingerprint sensing system according to claim 32, further comprising:
a light-filtering layer, disposed on the sensing pixels except the at least one environmental light sensing pixel and except the at least one first distance sensing pixel, and disposed between the optical layer and the sensor.

38. The fingerprint sensing system according to claim 37, further comprising:
a light-transmitting layer, disposed between the optical layer and the sensor, wherein the light-filtering pixel pattern layer is directly disposed at a position on the light-transmitting layer corresponding to the at least one environmental light sensing pixel.

39. The fingerprint sensing system according to claim 38, wherein the light-filtering pixel pattern layer is directly disposed at a position on the light-transmitting layer corresponding to the at least one first distance sensing pixel.

40. The fingerprint sensing system according to claim 38, wherein the light-filtering layer is directly disposed in a region of the light-transmitting layer corresponding to the sensing pixels except the at least one environmental light sensing pixel and except the at least one first distance sensing pixel.

41. The fingerprint sensing system according to claim 32, wherein the at least one environmental light sensing pixel comprises a plurality of environmental light sensing pixels, and the environmental light sensing pixels are symmetrically or evenly distributed around a central position of the sensor.

42. The fingerprint sensing system according to claim 41, wherein the light-filtering pixel pattern layer comprises at least two light-filtering pixels, light-filtering pixels corresponding to the at least one environmental light sensing pixel in the at least two light-filtering pixels are symmetrically or evenly distributed around the central position of the sensor.

43. The fingerprint sensing system according to claim 41, wherein the light-filtering pixel pattern layer comprises at least two light-filtering pixels and comprises at least two different transmittance spectrums, and light-filtering pixels having the same transmittance spectrum among light-filtering pixels of the light-filtering pixel pattern layer corresponding to the at least one environmental light sensing pixel are symmetrically or evenly distributed around the central position of the sensor.

44. The fingerprint sensing system according to claim 41, wherein the controller calculates the luminous intensity of the environmental light according to a ratio between the signals obtained by the environmental light sensing pixels, or obtains a frequency of change in the luminous intensity of the environmental light from a change of the signals with time.

45. The fingerprint sensing system according to claim 41, wherein part of the light-filtering pixel pattern layer corresponding to the at least one environmental light sensing pixel comprises at least three different transmittance spectrums, and the controller calculates a color temperature of the environmental light according to a ratio between the signals obtained by the environmental light sensing pixels.

46. The fingerprint sensing system according to claim 30, wherein the first light source is disposed on a side of the sensor adjacent to the at least one first distance sensing pixel.

47. The fingerprint sensing system according to claim 30, wherein the at least one first distance sensing pixel is located in a periphery region of the sensor.

48. The fingerprint sensing system according to claim 38, further comprising:
a second light source, used to emit a second light beam and electrically connected to the controller,
wherein the functional sensing pixels further comprise at least one second distance sensing pixel; and
wherein the controller controls the second light source to emit the second light beam, such that the object is irradiated by the second light beam to generate a second reflection light beam, and the controller calculates the distance between the object and the display according to a luminous intensity of the second reflection light beam, a time of flight, or a phase difference between light source modulation signals obtained by the at least one second distance sensing pixel.

49. The fingerprint sensing system according to claim 48, wherein the second light source is disposed on a side of the sensor adjacent to the at least one second distance sensing pixel.

50. The fingerprint sensing system according to claim 48, wherein the first light source and the second light source are respectively disposed on two different sides of the sensor.

51. The fingerprint sensing system according to claim 48, wherein the controller calculates a relative angle between the object and the display according to the luminous intensity of the first reflection light beam and the luminous intensity of the second reflection light beam.
